(19) United States
(12) Patent Application Publication
(10) Pub. No.: US 2005/0020061 A1
(43) Pub. Date: Jan. 27, 2005

(54) Method of modifying conductive wiring

(76) Inventors: Jui-Hua Fang, Taichung (TW); Cheng-Hui Chung, Hsinchu (TW); Chia-Hui Lu, Kaohsiung (TW)

Correspondence Address: BIRCH STEWART KOLASCH & BIRCH, PO BOX 747, FALLS CHURCH, VA, 22040-0747, US

(21) Appl. No.: 10/622,690

(22) Filed: Jul. 21, 2003

(51) Int. Cl. H01L 21/44

(52) U.S. Cl. 438/653; 438/652; 438/687; 438/660; 438/688

(57) ABSTRACT

A method of modifying a conductive wiring. First, a semiconductor substrate is provided. Next, a first barrier is formed on the semiconductor. A conductive wiring is formed on the first barrier. A second barrier is formed on the conductive wiring. Finally, a thermal treatment is performed on the semiconductor substrate.

### BACKGROUND OF THE INVENTION

1. Field of the Invention

The present invention relates to a semiconductor manufacturing process and in particular to a method of modifying conductive wiring.

2. Description of the Related Art

Metal wiring plays an important role in the semiconductor manufacturing technique. It is also very important to precisely integrate multiple layers of metal wiring in a chip. The development of metal wiring seeks to enhance reliability, reduce chip size, and enlarge the process window.

However, there are some difficulties in manufacturing metal wiring. Metal wiring is highly reflective, increasing difficulty in performing photolithography. An anti-reflective material is usually coated on the metal wiring to reduce its reflectivity, thereby enlarging the process window for photolithography.

Moreover, the material of the metal wiring usually comprises a Cu/Al/alloy or a Cu/Al/Si alloy. CuAl₂ precipitates are usually formed in the metal wiring, resulting in deleterious residue on the metal wiring after etching, in subsequent steps. The residue blocks the etchant removal of the underlying bottom TiN layer, and in effect causes electrical shorts, especially in the closely spaced metal wiring.

Furthermore, introduction of stress and the rough surface of the metal wiring due to the collapse of the photoresist layer are problematic.

### SUMMARY OF THE INVENTION

Accordingly, an object of the invention is to provide a method of modifying conductive wiring to avoid the problem of electrical shorts.

Another object of the invention is to provide a method of modifying conductive wiring to reduce its reflectivity, thereby benefiting photolithography.

Still another object of the invention is to provide a method of modifying conductive wiring to release residual stress in the conductive wiring.

A further object of the present invention is to provide a method of modifying conductive wiring to avoid CuAl₂ precipitates.

To achieve the above objects, one aspect of the present invention provides a method of modifying conductive wiring. First, a semiconductor substrate is provided. Next, a first barrier is formed on the semiconductor. Conductive wiring is formed on the first barrier. A second barrier is formed on the conductive wiring. Finally, a thermal treatment is performed on the semiconductor substrate.

The first barrier and the second barrier individually comprise a stacked Ti/TiN.

The conductive wiring comprises a Cu/Al alloy or a Cu/Al/Si alloy.

The substrate is quenched from a high temperature range of about 350° C. to a low temperature range of about 23° C. in a short interval between about 50 to 70 seconds.

One feature of the present invention is that a variety of methods for modifying the conductive wiring may be employed. One method of modification is a thermal treatment performed by quenching or baking. Another method of modification is the treatment of the nitrogen-containing gas.

Another feature of the present invention is that the modification can be performed in different steps, after forming the conductive wiring, after forming the Ti of the second barrier, or after forming TiN of the second barrier.

The nitrogen-containing gas comprises N₂O or N₂.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 through 4 are cross-sections showing the method of modifying a conductive layer according to one embodiment of the invention.

### DETAILED DESCRIPTION OF THE INVENTION

A preferred embodiment of the present invention is now described with reference to the figures.

### FIRST EMBODIMENT

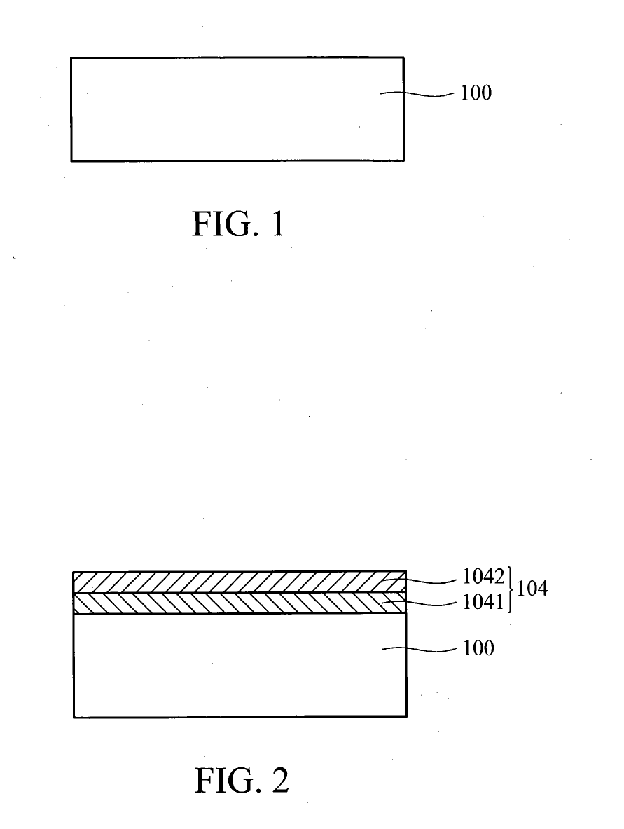

First, a semiconductor substrate 100 is provided, as shown in FIG. 1. The material of the semiconductor substrate 100 comprises silicon. The semiconductor substrate 100 can comprise and have desired elements, such as a MOS transistor, capacitor, or a logic device, although these elements are not shown in order to simplify the explanation.

Next, a first barrier 104 is formed, preferably on the semiconductor substrate 100 by physical vapor deposition (PVD), such as sputtering, at a temperature of about 90˜110° C., as shown in FIG. 2. During sputtering, a titanium target is used to form a Ti layer 1041 on the semiconductor substrate 100. Sputtering is then performed using the titanium target in an atmosphere of nitrogen; a TiN layer 1042 is thereby formed on the Ti layer 1041. Thus, the first barrier 104 comprises a stacked Ti/TiN layer. The thickness of Ti 1041 of the first barrier 104 is about 130˜170 Å. The thickness of TiN 1042 of the first barrier 104 is about 180˜220 Å.

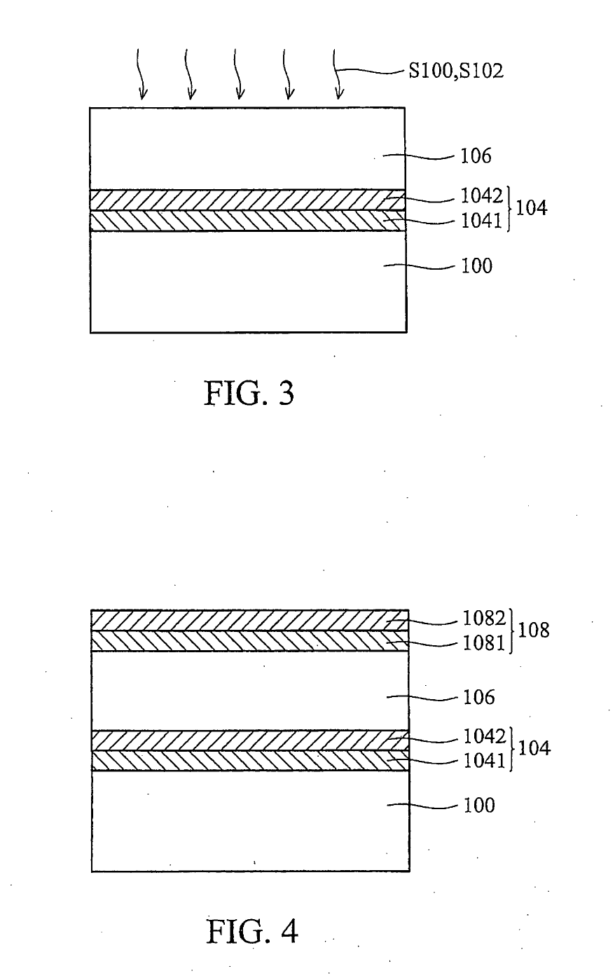

In FIG. 3, conductive wiring 106 is formed, preferably on the first barrier 104 at the temperature of about 270˜330° C. by physical vapor deposition (PVD), such as sputtering. The conductive wiring 106 comprises a Cu/Al alloy comprising 99.5% Al, 0.5% Cu or a Cu/Al/Si alloy comprising 98.5% Al, 0.5% Cu, and 1% Si in atomic ratio.

The key step of the present invention is the modified S100 comprising a thermal treatment, which can be performed after forming the conductive wiring 106. The thermal treatment S100 can be performed by ion bump or baking at the temperature of about 350° C. in an atmosphere of N₂O or N₂. Accordingly, the thermal treatment S100 is modified to prevent the formation of AlCu₂ precipitates, which result in deleterious residue in the conductive wiring 106 after etching, in subsequent steps. The residue blocks the etchant removal of the underlying first barrier 104, and in effect causes electrical shorts, especially between the closely spaced conductive wiring 106. Additionally, after the thermal treatment S100, stress in the conductive wiring 106 is released, and the uniformity of the conductive wiring 106 is improved. Furthermore, after quenching in step S100, the reflectivity of the conductive wiring 106 is reduced, benefiting photolithography.

In FIG. 4, a second barrier 108 is formed, preferably on the conductive wiring 106 by physical vapor deposition (PVD), such as sputtering, at a temperature of about 90˜110° C. During sputtering, a titanium target is used to form a Ti layer 1081 on the conductive wiring 106. Sputtering is then performed using the titanium target in an atmosphere of nitrogen; a TiN layer 1082 is thereby formed on the Ti layer 108. Thus, the second barrier 108 comprises a stacked Ti/TiN layer. The thickness of Ti 1081 of the first barrier 108 is about 90˜110 Å. The thickness of TiN 1082 of the first barrier 108 is about 650˜750 Å.

Alternately, according to the present invention, step S100 of the thermal treatment can be performed after forming the conductive wiring 106, after forming the Ti 1081 of the second barrier 108, or after forming the TiN 1082 of the second barrier 108.

### SECOND EMBODIMENT

First, a semiconductor substrate 100 is provided, as shown in FIG. 1. The material of the semiconductor substrate 100 comprises silicon. The semiconductor substrate 100 can comprise elements, such as a MOS transistor, capacitor, or a logic device, although these elements are not shown in order to simplify the explanation.

Next, a first barrier 104 is formed, preferably on the semiconductor substrate 100 by physical vapor deposition (PVD), such as sputtering, at the temperature of about 90˜110° C., as shown in FIG. 2. During sputtering, a titanium target is used to form a Ti layer 1041 on the semiconductor substrate 100. Sputtering is then performed using the titanium target in an atmosphere of nitrogen; a TiN layer 1042 is thereby formed on the Ti layer 1041. Thus, the first barrier 104 comprises a stacked Ti/TiN layer. The thickness of Ti 1041 of the first barrier 104 is about 130˜170 Å. The thickness of TiN 1042 of the first barrier 104 is about 180˜220 Å.

In FIG. 3, conductive wiring 106 is formed, preferably on the first barrier 104 at the temperature of about 200˜400° C. by physical vapor deposition (PVD), such as sputtering. The conductive wiring 106 comprises a Cu/Al alloy comprising 99.5% Al, 0.5% Cu or a Cu/Al/Si alloy comprising 98.5% Al, 0.5% Cu, and 1% Si in atomic ratio.

The key step of the present invention is the modified S102 comprising the treatment of a nitrogen-containing gas, which can be performed after forming the conductive wiring 106. The gas containing nitrogen can comprise N₂O or N₂. Accordingly, the method of modification of treating the nitrogen-containing gas S102 is performed to prevent the formation of AlCu₂ precipitates, and resulting deleterious residue in the conductive wiring 106 after etching, in subsequent steps. The residue blocks the etchant removal of the underlying first barrier 104, and in effect causes electrical shorts, especially between the closely spaced conductive wiring 106. Additionally, after treating the nitrogen-containing gas S102, stress in the conductive wiring 106 is released, and the uniformity of the conductive wiring 106 is improved. Furthermore, after treating nitrogen-containing gas S102, the reflectivity of the conductive wiring 106 is reduced, benefiting photolithography.

In FIG. 4, a second barrier 108 is formed, preferably on the conductive wiring 106 by physical vapor deposition (PVD) , such as sputtering, at the temperature of about 90˜110° C. During sputtering, a titanium target is used to form a Ti layer 1081 on the conductive wiring 106. Sputtering is then performed using the titanium target in an atmosphere of nitrogen; a TiN layer 1082 is thereby formed on the Ti layer 108. Thus, the first barrier 108 comprises a stacked Ti/TiN layer. The thickness of Ti 1081 of the first barrier 108 is about 90˜110 Å. The thickness of TiN 1082 of the first barrier 104 is about 650˜750 Å.

Alternately, according to the present invention, step S102 of treating the nitrogen-containing gas can be performed after forming the conductive wiring 106, after forming the Ti 1081 of the second barrier 108, or after forming the TiN 1082 of the second barrier 108.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art) Therefore, the scope of the appended claims should be accorded the broadest interpretation so as to encompass all such modifications and similar arrangements.

1. A method of modifying conductive wiring, comprising:
providing a semiconductor substrate;
forming a first barrier on the semiconductor substrate;
forming a conductive wiring on the first barrier;
performing a thermal treatment on the semiconductor substrate; and
forming a second barrier on the conductive wiring and after performing the thermal treatment.

2. The method as claimed in claim 1, wherein the first barrier and the second barrier individually comprises a stacked Ti/TiN.

3. The method as claimed in claim 1, wherein the conductive wiring comprises a Cu/Al alloy or a Cu/Al/Si alloy.

4. The method as claimed in claim 1, wherein the thermal treatment is performed by baking.

5. The method as claimed in claim 1, wherein the thermal treatment is performed by quenching.

6-7. (Cancelled)

8. The method as claimed in claim 1, wherein the thermal treatment is performed in an atmosphere containing nitrogen.

9. (Cancelled)

10. The method as claimed in claim 1, wherein the thermal treatment is performed at a temperature of about 200˜400° C.

11. The method as claimed in claim 5, wherein the substrate is quenched from a high temperature range of about 350° C. to a low temperature range of about 23° C. in a short interval between about 50 to 70 seconds.

12. A method of modifying conductive wiring, comprising:
providing a semiconductor substrate;
forming a first barrier on the semiconductor substrate;
forming a conductive wiring on the first barrier;
treating the semiconductor substrate with a nitrogen-containing gas; and
forming a second barrier on the conductive wiring after treating the semiconductor substrate with the nitrogen-containing gas.

13. The method as claimed in claim 12, wherein the first barrier and the second barrier individually comprise a stacked Ti/TiN.

14. The method as claimed in claim 12, wherein the conductive wiring comprises a Cu/Al alloy or a Cu/Al/Si alloy.

15-17. (Cancelled)

18. The method as claimed in claim 12, wherein the nitrogen-containing gas comprises N₂O or N₂.

19-20. (Cancelled)
